(19) United States
(12) Patent Application Publication
(10) Pub. No.: US 2026/0183871 A1
(43) Pub. Date: Jul. 2, 2026

(54) LASER DRILLING SYSTEM AND METHOD FOR SELECTIVE REMOVAL OF INSULATING LAYERS

(71) Applicant: Absolics Inc., Covington, GA (US)

(72) Inventors: Chun Jae LEE, Covington, GA (US); YONG HA WOO, Covington, GA (US)

(73) Assignee: Absolics Inc., Covington, GA (US)

(21) Appl. No.: 19/435,574

(22) Filed: Dec. 29, 2025

Related U.S. Application Data
(60) Provisional application No. 63/740,335, filed on Dec. 31, 2024.

(51) Int. Cl. B23K 26/362; G02B 27/28; G02F 1/137; H10P 72/00

(52) U.S. Cl. CPC B23K 26/362; G02B 27/286; G02B 27/288; G02F 1/137; H10P 72/0428; G02F 2203/50

(57) ABSTRACT

The embodiment relates to a laser drilling system and a method for selectively removing an insulating layer, and comprises: a workpiece including a metal layer and an insulating layer disposed on the metal layer; a stage on which the workpiece is placed; an optical delivery system disposed on the stage and configured to deliver laser light to the insulating layer; a laser beam generator connected to the optical delivery system and configured to output laser light; a blowing-suction device disposed between the workpiece and the optical delivery system; a monitoring-inspection device configured to inspect the surface shape of the workpiece; and a control unit configured to control the laser light generated by the laser beam generator and/or the optical delivery system based on the surface shape information, wherein the optical delivery system controls the laser light by means of a diffractive optical system.

### CROSS-REFERENCE TO RELATED APPLICATION

This application claims priority of U.S. Provisional Patent Application No. 63/740,335, filed on Dec. 31, 2024, the entire disclosure of which is hereby incorporated by reference for all purposes.

### BACKGROUND

### Technical Field

The embodiment relates to a laser drilling system and a method for selectively removing insulating layers, which may simplify the process for efficient implementation, and which may allow the formation of holes even in cases where conventional exposure techniques have difficulty forming intended hole shapes, such as small holes or those with a high aspect ratio.

### Description of Related Art

In the manufacturing process for electronic components, front-end (FE) processes may implement circuits on semiconductor wafers, and back-end (BE) processes may assemble the wafers into a form usable as actual products. The packaging process may be included in the back-end processes.

Among the four core technologies of the semiconductor industry that have enabled the remarkable development of modern electronic devices are semiconductor technology, semiconductor packaging, semiconductor manufacturing, and software technology.

Semiconductor technology has advanced in various areas, including submicron or nanoscale line width, the integration of over ten million cells, high-speed operation, and heat dissipation. However, such developments may not be fully supported without complete packaging technology. Accordingly, the electrical performance of semiconductors may be determined not only by the performance of the semiconductor technology itself but also by the packaging technology and the resulting electrical interconnections.

One of the methods introduced to improve electrical performance is vertical interconnection. A via is one example of such a vertical interconnection structure, and laser drilling may be applicable for forming the via. When forming small vias using lithographic methods such as exposure and development, technical difficulties may arise as the depth of the via holes increases. For example, it is difficult to reliably secure the external shape of the hole, such as the hole opening size and the aspect ratio, so additional processes such as plasma etching may be required, resulting in process complexity, equipment burden, and yield reduction.

Meanwhile, the aforementioned background technologies are technical information that the inventor possessed or acquired in the course of deriving the present invention, and are not necessarily publicly known prior art disclosed to the general public before the filing of the present invention.

Examples of related art include Korean Registered Patent No. 10-2477657 and Korean Laid-Open Patent Publication No. 10-2016-0110780.

### SUMMARY

This summary is provided to explain some simplified concepts that are further described in detail in the following detailed description. This summary is not intended to identify key features or essential characteristics of the claimed subject matter, nor is it intended to be used to limit the scope of the claimed subject matter.

In some embodiments, a laser drilling system and the like that may simplify the process and allow efficient implementation is provided.

In some embodiments, a laser drilling system and the like that may form patterns of different shapes, sizes, and depths—such as lines, holes, and pads—substantially in a single laser drilling operation is provided.

In some embodiments, a laser drilling system and the like that may allow the formation of holes even in cases where conventional exposure techniques have difficulty forming intended hole shapes, such as small holes or those with a high aspect ratio is provided.

According to the embodiments, a laser drilling system includes: a workpiece including a metal layer and an insulating layer disposed on the metal layer; a stage on which the workpiece is mounted; an optical delivery system disposed on the stage and configured to deliver laser light to the insulating layer; a laser beam generator connected to the optical delivery system and configured to output the laser light; a blowing-suction device disposed between the workpiece and the optical delivery system; a monitoring-inspection device configured to inspect the surface shape of the workpiece; and a control unit configured to control the laser light generated by the laser beam generator and/or the optical delivery system based on the surface shape information. The optical delivery system controls the laser light through a diffractive optical system.

The diffractive optical system may apply a patterned quasi-binary phase mask.

The optical delivery system may filter the laser light into linearly polarized light, pattern the light by the diffractive optical system according to information provided by the control unit to implement regionally different light intensities, and then convert the linear polarization into circular polarization before delivering it to the workpiece.

The optical delivery system may include: a primary beam quality control unit through which the laser light generated by the laser beam generator passes; a diffractive optical system that modulates the light passing through the primary beam quality control unit; and a circular polarization unit that converts the light passing through the diffractive optical system into circularly polarized light.

The circular polarization unit may include: a first circular polarizing plate through which the light modulated by the diffractive optical system passes; a polarizing plate through which the light having passed through the first circular polarizing plate passes; and a second circular polarizing plate through which the light having passed through the polarizing plate passes.

The diffractive optical system may include a spatial light modulator.

The spatial light modulator may include liquid crystal arranged to induce phase modulation and amplitude modulation of the laser light.

The diffractive optical system may include a liquid crystal panel-type spatial light modulator, a micromirror array-based spatial light modulator, a deformable mirror, or a diffractive optical element.

According to the embodiments, a method for selectively removing insulating layers includes: a placement operation of placing a workpiece on a stage; and an etching operation of irradiating the workpiece with secondary laser light, which is generated by passing primary laser light output from a laser beam generator through an optical delivery system to which a diffractive optical system is applied.

The workpiece includes a metal layer and an insulating layer disposed on the metal layer, and the secondary laser light may form a pattern including via holes, pads, lines, or any combination thereof in the insulating layer.

The etching operation may include: a primary processing operation in which the primary laser light passes through a beam quality control unit via the optical delivery system; and a secondary processing operation in which the primary laser light passes through the diffractive optical system and is emitted as secondary laser light having a pattern and intensity adjusted according to the shape to be processed.

The etching operation may further include a control operation.

The control operation may include: a process of verifying whether an abnormal intensity or shape of zero-order light occurs in the diffractive optical system; and a process of adjusting the abnormal intensity and shape to be located on a dummy or a pad of the workpiece.

### BRIEF DESCRIPTION OF THE DRAWINGS

FIG. 1 is a conceptual diagram illustrating a laser drilling system according to an embodiment.

FIG. 2 is a conceptual cross-sectional diagram illustrating the etching operation performed in an optical delivery system according to an embodiment.

FIG. 3 is a conceptual diagram illustrating an optical delivery system according to an embodiment.

### DESCRIPTION OF THE EMBODIMENTS

The following detailed description is provided to aid in a comprehensive understanding of the methods, devices, and/or systems described in this specification. However, it will be apparent, after reading the present disclosure, that various changes, modifications, and equivalents to the methods, devices, and/or systems described herein may be made. For example, the order of operations described herein is provided by way of example only and is not intended to be limiting. The sequence of operations described herein may be clearly modified after understanding the present disclosure, and not all operations are necessarily required to be performed in a particular order. In addition, descriptions of known features may be omitted for clarity and conciseness after understanding the present disclosure, and such omissions are not to be construed as an acknowledgment that such features are common general knowledge.

Features described in this specification may be implemented in various forms and should not be interpreted as limited to the specific examples described herein. Rather, the examples are provided merely to illustrate some of the many possible ways of implementing the methods, devices, and/or systems described in this disclosure after understanding the invention.

Throughout this specification, terms such as “first,” “second,” and “third” may be used to describe various elements, components, regions, layers, or sections. However, such terms are not intended to limit the elements. Rather, these terms are used merely to distinguish one element, component, region, layer, or section from another. Accordingly, a “first” element, component, region, layer, or section described in one embodiment may also be referred to as a “second” element, component, region, layer, or section without departing from the teachings of the embodiment.

Throughout this specification, when an element such as a layer, region, or substrate is described as being “on,” “connected to,” or “coupled to” another element, it may be directly “on,” “connected to,” or “coupled to” the other element, or one or more intervening elements may be present. In contrast, when an element is described as being “directly on,” “directly connected to,” or “directly coupled to” another element, there are no intervening elements present between them. Likewise, expressions such as “between” and “directly between,” or “indirectly introduced” and “directly introduced,” may be interpreted in accordance with the foregoing descriptions.

The terminology used in this specification is for the purpose of describing particular examples only and is not intended to limit the scope of the disclosure. As used herein, the singular forms “a,” “an,” and “the” include the plural forms as well, unless the context clearly indicates otherwise. The terms “and/or” as used herein include any and all combinations of one or more of the listed items. The terms “include,” “comprise,” and “have” as used herein specify the presence of stated features, numbers, operations, elements, components, and/or combinations thereof, but do not preclude the presence or addition of one or more other features, numbers, operations, elements, components, and/or combinations thereof. The term “may” as used in connection with embodiments (for example, with regard to features that may be included or implemented in an example or embodiment) indicates that at least one embodiment or example comprises such a feature, but that all embodiments are not necessarily limited to such a configuration.

Throughout this specification, the expression that “B is disposed on A” means that B may be disposed directly on A in contact therewith or may be disposed on A with one or more other layers or structures interposed therebetween. It is not to be construed as being limited to direct contact between B and A. Unless otherwise defined, all terms used in this document shall be interpreted based on the understanding of this document, and shall have the same meaning as commonly understood by those skilled in the relevant technical field after reviewing this specification.

Terms that are generally defined in commonly used dictionaries should be interpreted as having meanings consistent with their usage in the relevant technical field and the context of the present disclosure, and should not be interpreted in an idealized or overly formal sense unless explicitly defined herein.

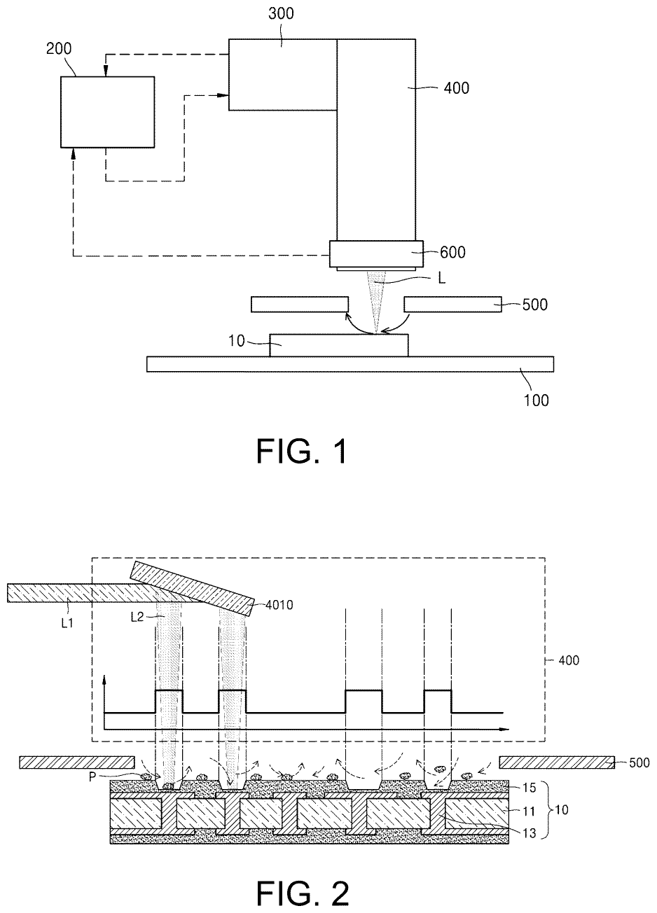

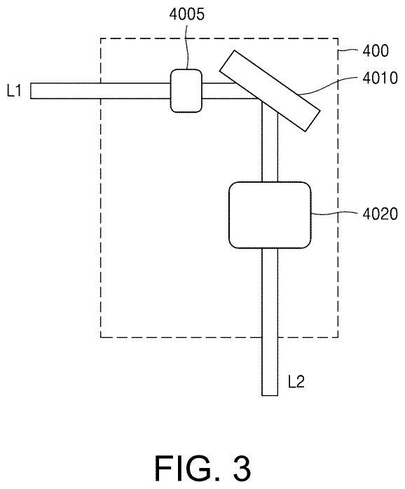

FIG. 1 is a conceptual diagram illustrating a laser drilling system according to an embodiment, and FIG. 2 is a conceptual cross-sectional diagram illustrating the etching operation performed in an optical delivery system according to an embodiment. FIG. 3 is a conceptual diagram illustrating the optical delivery system according to an embodiment. With reference to these drawings, the following embodiment will now be described in greater detail.

To achieve the above object, a laser drilling system according to one embodiment of the present disclosure comprises: a stage 100; an optical delivery system 400; a laser beam generator 300; a blowing-suction device 500; a monitoring-inspection device 600; and a control unit 200 (see FIG. 1).

These components are interconnected and perform selective etching of a workpiece 10 within the laser drilling system.

The workpiece 10 comprises a metal layer 13 and an insulating layer 15 disposed on the metal layer 13 (see FIG. 2).

By way of example, the workpiece 10 may be a packaging substrate used for packaging semiconductor elements. When the workpiece 10 is applied as a packaging substrate, a glass core 11 may be used. Specifically, the workpiece 10 may comprise: a glass core 11 having through-vias; metal layers 13 disposed on both surfaces of the glass core 11 and within the through-vias; and insulating layers 15 disposed on the metal layers 13.

The workpiece 10 has insulating layers disposed thereon, and the metal layers may be located above and/or below the insulating layers. The selective removal of the insulating layers allows a metal layer (conductive layer) to be formed on the workpiece 10 in a subsequent process, which may serve as a wiring pattern in the packaging substrate.

In conventional processes, the formation of a metal layer (conductive layer) required a highly complex and multi-step sequence.

Conventionally, in order to form a pattern including holes, pads, and lines on the workpiece, the following process was performed: 1) cleaning the substrate; 2) forming a metal layer by sputtering or the like; 3) performing pretreatment; 4) carrying out a lithography process; 5) plating; 6) annealing and etching; 7) cleaning again; 8) performing pretreatment again; 9) applying an insulating material; 10) curing to form an insulating layer; 11) forming via holes; 12) performing a desmear process; 13) cleaning; 14) forming a metal layer again; 15) performing pretreatment; 16) conducting another lithography process; 17) plating; and 18) annealing and etching again. This entire cycle was repeated to form a single patterned layer.

In the embodiment, patterning of the insulating layer is achieved by removing the areas to be patterned—such as holes, pads, and lines—not through separate steps for each, but through a laser drilling process that enables simultaneous patterning. This allows simplification and efficiency of the process. Once the patterned regions in the insulating layer are removed in this manner, metal layers in the form of patterns can be effectively formed by subsequent plating or similar processes.

The stage 100 is a device on which the workpiece 10 is placed.

The workpiece 10 may be positioned on the stage 100 by an automated device (e.g., a robotic arm), and its position after placement may be checked and adjusted by the monitoring-inspection device 600 and the control unit 200. At this time, the workpiece 10 may comprise an alignment mark (not shown), and the relative position of the workpiece 10 with respect to the stage 100 may be detected by the monitoring-inspection device 600. When this information is transmitted to the control unit 200, the control unit 200 may determine whether the position is appropriate and adjust the position of the workpiece 10 accordingly.

The laser beam generator 300 is connected to the optical delivery system 400 and outputs laser light L.

The laser light L may have an absorption characteristic suitable for processing metallic materials such as copper or titanium. In addition, the laser light L may have an absorption characteristic suitable for processing organic layers or organic-inorganic composite layers, such as insulating layers (e.g., a cured layer of Ajinomoto build-up film), polyimide layers, or photoresist layers.

Specifically, the laser light L may have a UV wavelength. For example, the laser light L may have a wavelength of 400 nm or less, 350 nm or less, 340 nm or less, 330 nm or less, 320 nm or less, 310 nm or less, 300 nm or less, 290 nm or less, 280 nm or less, 270 nm or less, 260 nm or less, or 250 nm or less. The laser light L may have a wavelength of 100 nm or more.

The laser light L may have a pulse energy of 10 mJ or more, 15 mJ or more, 20 mJ or more, 25 mJ or more, 30 mJ or more, 35 mJ or more, 40 mJ or more, 45 mJ or more, 50 mJ or more, 55 mJ or more, 60 mJ or more, 65 mJ or more, 70 mJ or more, or 75 mJ or more. The pulse energy may be 200 mJ or less, 150 mJ or less, or 1 J or less. Applying such pulse energy may allow more efficient removal of the insulating layer or the like.

The laser light L may have a pulse repetition rate of 10 Hz or more, 50 Hz or more, 100 Hz or more, 300 Hz or more, 600 Hz or more, 900 Hz or more, 1,000 Hz or more, 2,000 Hz or more, 3,000 Hz or more, 4,000 Hz or more, or 5,000 Hz or more. The pulse repetition rate may be 10 kHz or less.

The laser light L may be capable of processing with high resolution while simultaneously applying relatively high repetition rate and relatively high energy.

When the depth is 20 μm or less, the laser light L may allow the reliable formation of vias having a diameter of 20 μm or less.

However, the laser light L is not limited to the characteristics described above.

The optical delivery system 400 is disposed on the stage 100 and delivers laser light L to the insulating layer 15.

The laser light L is not delivered directly to the workpiece 10, but rather laser light that has been transformed through the optical delivery system 400 is delivered.

The laser light L output from the laser beam generator 300 is referred to as primary laser light L1, and the light emitted toward the insulating layer 15 from the optical delivery system 400 is referred to as secondary laser light L2.

In the optical delivery system 400, the primary laser light L1 is converted into secondary laser light L2 by the diffractive optical system 4010.

The optical delivery system may filter the laser light into linearly polarized light, pattern the light based on information provided by the control unit via the diffractive optical system 4010 to implement regionally different light intensities, and convert the linearly polarized light into circularly polarized light before delivering it to the workpiece.

The diffractive optical system 4010 may apply a patterned quasi-binary phase mask.

The diffractive optical system 4010 may comprise a spatial light modulator (SLM).

The diffractive optical system 4010 may comprise a liquid crystal-based spatial light modulator.

The diffractive optical system 4010 may comprise a digital micromirror device (DMD)-based spatial light modulator.

The diffractive optical system 4010 may comprise a deformable mirror.

The diffractive optical system 4010 may comprise a diffractive optical element (DOE).

The diffractive optical system 4010 may comprise phase modulation and amplitude modulation of the laser light.

The optical delivery system 400 may comprise: a primary beam quality control unit 4005 through which the laser light generated by the laser beam generator passes; the diffractive optical system 4010 for modulating the light passing through the primary beam quality control unit 4005; and a circular polarization unit 4020 that converts the light passing through the diffractive optical system 4010 into circularly polarized light.

A lens (not shown) may be further disposed at the rear end of the circular polarization unit 4020.

The primary beam quality control unit 4005 may comprise, for example, a half-wave plate (HWP).

The diffractive optical system 4010 is as described above.

The circular polarization unit 4020 comprises a quarter wave plate (QWP), which converts linearly polarized light into circularly polarized light.

The circular polarization unit 4020 may comprise: a first quarter wave plate (QWP) through which the light modulated by the diffractive optical system 4010 passes; a polarizer through which the light passing through the first quarter wave plate passes; and a second quarter wave plate (QWP) through which the light passing through the polarizer passes.

The light having passed through the circular polarization unit 4020 may further pass through a secondary beam quality control unit (not shown). For example, the secondary beam quality control unit may comprise lenses and the like, but is not limited thereto.

The optical delivery system 400 may allow laser etching of patterns having different shapes and depths—such as holes, lines, and pads—without applying a physically patterned mask, but instead by inducing changes in, for example, a liquid crystal. Furthermore, high-resolution etching of the insulating layer at high speed is possible. Since the laser irradiation process can be carried out while modifying the pattern by controlling the properties of the diffractive optical system disposed inside the optical delivery system, without separately applying a patterned mask, the process speed and efficiency can be significantly improved.

The laser light L, delivered through the optical delivery system 400, may form a pattern in the insulating layer 15, the pattern comprising: via holes with controlled depth and diameter; pads with controlled depth and diameter; lines with controlled depth and width; or any combination thereof.

The pattern is formed through etching by the laser light. This pattern is formed by selectively removing portions of the insulating layer. If particulate by-products remain within the etched pattern of the insulating layer, subsequent cleaning processes may become complicated, and disconnection or breakage may occur in subsequent processes.

During the etching process by the laser light L, particulate contaminants or smear P as machining by-products may be generated. These must be removed before proceeding to subsequent processes.

The blowing-suction device 500 removes the particulate contaminants or smear P generated during removal of the insulating layer 15 by the laser light L, using air pressure to clean them from the insulating layer 15.

The blowing-suction device 500 is disposed between the workpiece 10 and the optical delivery system 400. This arrangement may facilitate the removal of particulate contaminants or smear.

The blowing operation may utilize, for example, gases such as clean dry air (CDA) or nitrogen (N₂), but is not limited thereto.

The particulate by-products or smear may remain in portions of the etched pattern or may fall onto the insulating layer. Optionally, a processing protection layer (not shown) may be disposed on the insulating layer, thereby allowing easier removal of the particulate by-products or smear.

Specifically, the particulate by-products or smear may be induced to fall not directly onto the surface of the insulating layer but onto the processing protection layer. As a result, the particulate by-products or smear may be more easily removed by subsequently removing the processing protection layer. In this manner, the removal of the protection layer during subsequent cleaning or other processes may effectively remove the particulate by-products or smear.

The monitoring-inspection device 600 is a device configured to inspect surface shape information of the workpiece 10.

The control unit 200 controls the laser light L generated from the laser beam generator 300 and/or the optical delivery system 400 based on the surface shape information.

The monitoring-inspection device 600 and the control unit 200 acquire information from the workpiece and perform operations based on that information to enable proper laser irradiation and selective removal of the insulating layer.

For example, the workpiece 10 may comprise alignment marks, and the control unit 200 may control the position of the workpiece 10 and/or the position of the laser irradiation based on the alignment marks.

As another example, the control unit 200 may control the processing height by the laser light L based on the alignment marks of the workpiece 10.

As yet another example, the control unit 200 may control the focal size of the laser light L based on the alignment marks of the workpiece 10.

The control unit 200 may control the temperature and humidity within the laser drilling system.

Using the laser drilling system, etched patterns may be sequentially formed in divided regions of the insulating layer. The shape, width, and depth of the pattern may be controlled by controlling the laser light, allowing highly accurate laser drilling to be performed in a relatively short process time.

A method for removing an insulating layer according to another embodiment comprises: a placement operation; and an etching operation, in which the insulating layer of a workpiece is etched to form a recessed pattern.

The placement operation comprises controlling the position of the workpiece 10 and placing it on the stage 100.

The placement operation may further comprise fixing the workpiece 10 on the stage 100 using clamping or vacuum and alleviating warpage.

The workpiece 10 comprises a metal layer 13 and an insulating layer 15 disposed on the metal layer 13. The metal layer 13 may be an electrically conductive layer (i.e., a patterned metal layer) located beneath the insulating layer in a packaging substrate. Alternatively, the metal layer 13 may be a seed layer located beneath the insulating layer in the packaging substrate.

The insulating layer 15 may be an organic layer or an organic-inorganic composite layer. For example, the insulating layer may be provided by placing a sheet-shaped insulating material on the metal layer 13 together with a release film such as PET film, followed by vacuum lamination and then curing or semi-curing.

The release film, such as the PET film, may optionally serve as the processing protection layer described above.

In the etching operation, primary laser light L1 output from the laser beam generator 300 is converted into secondary laser light L2, which is then irradiated onto the workpiece 10. Specifically, the primary laser light output from the laser beam generator is passed through an optical delivery system with an applied diffractive optical system, converted into secondary laser light, and irradiated onto the workpiece to etch a predetermined shape and depth.

The secondary laser light L2 forms a pattern in the insulating layer 15, the pattern comprising via holes, pads, lines, or a combination thereof.

The etching operation may comprise: a primary processing operation in which the primary laser light passes through a beam quality control unit via the optical delivery system; and a secondary processing operation in which the primary laser light passes through a diffractive optical system and is emitted as secondary laser light whose pattern and intensity are adjusted according to the target shape.

Specifically, the laser beam emitted from the laser source passes through a beam quality control unit in the optical delivery system as a first step, and then passes through a diffractive optical system that defines the machining pattern, ultimately reaching the processing location, allowing simultaneous machining of holes and patterns.

The etching operation may further comprise a control operation.

The control operation may comprise: a process of checking whether an abnormal intensity or shape of zero-order light is generated in the diffractive optical system; and a process of adjusting the abnormal intensity and shape to be positioned on a dummy or pad region of the workpiece.

The method for removing the insulating layer may further comprise a particle removal operation, which is performed simultaneously with or after the etching operation.

The particle removal operation may remove or collect particulate contaminants or smear P on the surface of the workpiece 10 by blowing, suction, or both.

The control operation comprises checking and controlling machining parameters.

The machining parameters may comprise position alignment of the workpiece 10, key recognition of the alignment mark, height of the etching target on the workpiece 10, and processing drawing data having target information for machining.

The control operation may control the etching operation to proceed on a unit-by-unit basis for holes, pads, and lines.

The laser drilling system according to the embodiment may simplify the process and enable efficient implementation, and may allow the formation of patterns having different shapes, sizes, and depths—such as lines, holes, and pads—substantially in a single laser drilling operation. In addition, it may allow the formation of holes even in cases where conventional exposure techniques have difficulty forming intended hole shapes, such as small holes or those with a high aspect ratio.

While preferred embodiments of the present invention have been described above in detail, the scope of the present invention is not limited thereto, and various modifications and improvements based on the basic concept defined in the following claims by those skilled in the art are also included within the scope of the present invention.

What is claimed is:

1. A laser drilling system comprising:
a workpiece comprising a metal layer and an insulating layer disposed on the metal layer;
a stage on which the workpiece is placed;
an optical delivery system disposed on the stage and configured to deliver laser light to the insulating layer;
a laser beam generator connected to the optical delivery system and configured to output the laser light;
a blowing-suction device disposed between the workpiece and the optical delivery system;
a monitoring-inspection device configured to inspect a surface shape of the workpiece; and
a control unit configured to control the laser light generated by the laser beam generator and/or the optical delivery system based on the surface shape,
wherein the optical delivery system controls the laser light by a diffractive optical system.

2. The laser drilling system of claim 1,
wherein the diffractive optical system applies a patterned quasi-binary phase mask.

3. The laser drilling system of claim 1,
wherein the optical delivery system filters the laser light into linearly polarized light, patterns the light based on information provided by the control unit via the diffractive optical system to implement regionally different light intensities, and then converts the linearly polarized light into circularly polarized light to deliver to the workpiece.

4. The laser drilling system of claim 1,
wherein the optical delivery system comprises:
a primary beam quality control unit through which the laser light generated from the laser beam generator passes;
a diffractive optical system for modulating the light having passed through the primary beam quality control unit; and
a circular polarization unit for converting the light having passed through the diffractive optical system into circularly polarized light.

5. The laser drilling system of claim 4,
wherein the circular polarization unit comprises:
a first quarter wave plate through which the light modulated by the diffractive optical system passes;
a polarizer through which the light having passed through the first quarter wave plate passes; and
a second quarter wave plate through which the light having passed through the polarizer passes.

6. The laser drilling system of claim 1,
wherein the diffractive optical system comprises a spatial light modulator,
and the spatial light modulator comprises liquid crystals configured to induce phase modulation and amplitude modulation of the laser light.

7. The laser drilling system of claim 1,
wherein the diffractive optical system comprises a liquid crystal-based spatial light modulator, a digital micromirror device-based spatial light modulator, a deformable mirror, or a diffractive optical element.

8. A method for selectively removing an insulating layer, comprising:
a placement operation of placing a workpiece on a stage; and
an etching operation of irradiating the workpiece with secondary laser light generated by passing primary laser light output from a laser beam generator through an optical delivery system to which a diffractive optical system is applied,
wherein the workpiece comprises a metal layer and an insulating layer disposed on the metal layer,
and the secondary laser light forms a pattern in the insulating layer, the pattern comprising via holes, pads, lines, or any combination thereof.

9. The method of claim 8,
wherein the etching operation comprises:
a primary processing operation in which the primary laser light passes through a beam quality control unit via the optical delivery system; and
a secondary processing operation in which the primary laser light passes through the diffractive optical system and is emitted as secondary laser light whose pattern and intensity are adjusted according to a shape to be processed.

10. The method of claim 9,
wherein the etching operation further comprises a control operation,
and the control operation comprises:
checking whether abnormal intensity or shape of zero-order light occurs in the diffractive optical system; and
adjusting the abnormal intensity and shape to be positioned on a dummy or pad of the workpiece.
